(19) United States
(12) Patent Application Publication
(10) Pub. No.: US 2025/0366030 A1
(43) Pub. Date: Nov. 27, 2025

(54) THIN FILM TRANSISTOR, METHOD OF MANUFACTURING THE SAME, AND ELECTRONIC DEVICE

(71) Applicant: Samsung Display Co., LTD., Yongin-si (KR)

(72) Inventors: Kang Hyun KIM, Yongin-si (KR); Young Gil PARK, Yongin-si (KR)

(73) Assignee: Samsung Display Co., LTD., Yongin-si (KR)

(21) Appl. No.: 19/057,492

(22) Filed: Feb. 19, 2025

(30) Foreign Application Priority Data
May 27, 2024 (KR) 10-2024-0068537

(51) Int. Cl. H10D 30/67; H10D 30/01

(52) U.S. Cl. CPC H10D 30/6713; H10D 30/031; H10D 30/6755; H10D 30/6758

(57) ABSTRACT

A thin film transistor includes a substrate, a barrier layer disposed on the substrate, and an active pattern layer disposed on the barrier layer and including a first region and second regions adjacent to the first region. The second regions include openings having a circular shape or a polygonal shape.

### CROSS-REFERENCE TO RELATED APPLICATION(S)

This application claims priority to and benefits of Korean Patent Application No. 10-2024-0068537 under 35 U.S.C. § 119, filed on May 27, 2024, in the Korean Intellectual Property Office, the entire contents of which are incorporated herein by reference.

### BACKGROUND

### 1. Technical Field

The disclosure relates to a thin film transistor, a method of manufacturing the thin film transistor, and an electronic device including the thin film transistor.

### 2. Description of the Related Art

Transistors are widely used as switching devices or driving devices in the field of electronic devices. In particular, thin film transistors are useful in the field of display devices because they are manufactured on a glass or plastic substrate.

### SUMMARY

Embodiments provide a thin film transistor capable of eliminating (or reducing) a change in characteristics (or degradation of characteristics) due to external influences, a method of manufacturing the thin film transistor, and an electronic device including the thin film transistor.

However, embodiments are not limited to those set forth herein. The above and other embodiments will become more apparent to one of ordinary skill in the art to which the disclosure pertains by referencing the detailed description of the disclosure given below.

According to an embodiment, a thin film transistor may include a substrate; a barrier layer disposed on the substrate; and an active pattern layer disposed on the barrier layer and including a first region and second regions adjacent to the first region, and the second regions may include openings.

The openings may be arranged regularly.

The openings may be arranged irregularly.

The openings may have a circular shape or a polygonal shape.

A size of the openings may vary according to a width of the active pattern layer and a length of each of the second regions.

The size of the openings may be about 10% to about 80% of a size of the second regions.

The openings may discharge gas flowing into the second regions.

The gas may include at least one of hydrogen, oxygen, moisture, and etching gas.

The active pattern layer may include an oxide semiconductor.

The thin film transistor may further include a gate insulating pattern layer disposed on the first region; a gate electrode disposed on the gate insulating pattern layer; a passivation layer covering the barrier layer, the active pattern layer, the gate insulating pattern layer, and the gate electrode; a source electrode penetrating the passivation layer and electrically connected to one of the second regions; and a drain electrode penetrating the passivation layer and electrically connected to another one of the second regions.

According to an embodiment, a method of manufacturing a thin film transistor may include forming an active layer on a barrier layer on a substrate; forming an active pattern layer by etching the active layer; forming a first region and second regions adjacent to the first region by partially doping the active pattern layer; and forming openings in the second regions.

The first region may be an undoped region, and the second regions may be doped regions.

The openings may discharge hydrogen flowing into the second regions from the barrier layer.

The method may further include forming a gate insulating layer covering the barrier layer and the active pattern layer; and etching the gate insulating layer to form a gate insulating pattern layer on the first region.

The openings may discharge etching gas flowing into the second regions during a process of etching the gate insulating layer.

The method may further include forming a gate electrode on the gate insulating pattern layer; and forming a passivation layer to cover the barrier layer, the active pattern layer, the gate insulating pattern layer, and the gate electrode.

The openings may discharge hydrogen flowing into the second regions from the passivation layer.

The method may further include forming a first contact hole and a second contact by etching the passivation layer.

The openings may discharge etching gas flowing into the second regions during a process of etching the passivation layer.

The method may further include forming a source electrode electrically connected to one of the second regions through the first contact hole; and forming a drain electrode electrically connected to another one of the second regions through the second contact hole.

According to an embodiment, an electronic device may include a processor to provide input image data; and a display device to display an image based on the input image data, the display device including a thin film transistor. The thin film transistor may include a substrate; a barrier layer disposed on the substrate; and an active pattern layer disposed on the barrier layer and including a first region and second regions adjacent to the first region, and the second regions may include openings.

### BRIEF DESCRIPTION OF THE DRAWINGS

The above and other features of the disclosure will become more apparent by describing in further detail embodiments thereof with reference to the accompanying drawings, in which:

FIG. 1 is a schematic cross-sectional view illustrating a thin film transistor according to an embodiment.

FIG. 2 is a schematic cross-sectional view illustrating a change in channel length in the thin film transistor of FIG. 1.

FIG. 3 is a schematic cross-sectional view illustrating a thin film transistor according to an embodiment.

FIG. 4 is a schematic cross-sectional view illustration an active pattern layer of FIG. 3 according to an embodiment.

FIG. 5 is a schematic cross-sectional view illustrating the active pattern layer of FIG. 3 according to an embodiment.

FIGS. 6 to 15 are schematic cross-sectional views illustrating a method of manufacturing a thin film transistor according to an embodiment.

FIG. 16 is a block diagram of an electronic device according to an embodiment.

FIG. 17 shows schematic views of various embodiments of an electronic device.

### DETAILED DESCRIPTION OF THE EMBODIMENTS

Hereinafter, a preferred embodiment according to the disclosure is described in detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiment described herein. However, the embodiment described herein is provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and embodiments are not limited thereto.

Hereinafter, embodiments of the disclosure are described in detail with reference to the accompanying drawings.

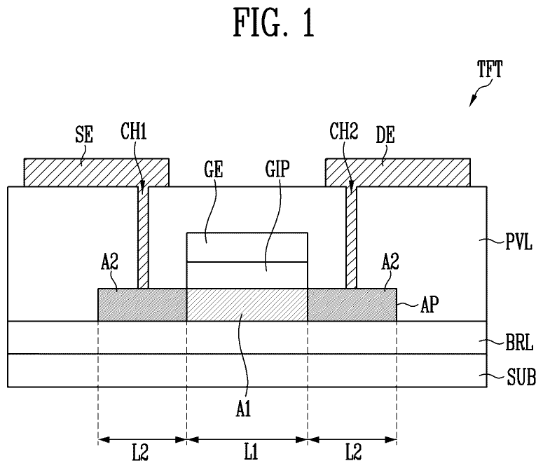

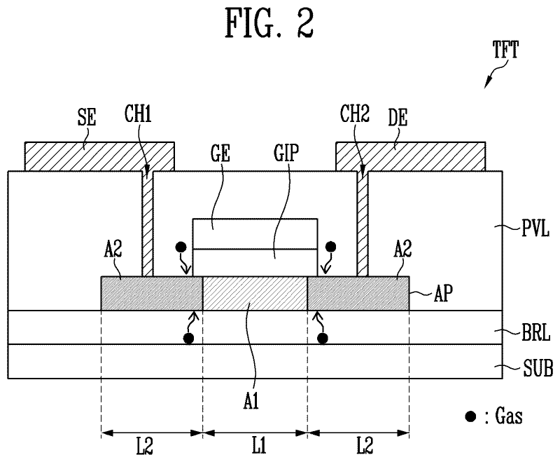

FIG. 1 is a schematic cross-sectional view illustrating a thin film transistor according to an embodiment. FIG. 2 is a schematic cross-sectional view illustrating a change in channel length in the thin film transistor of FIG. 1.

Referring to FIGS. 1 and 2, a barrier layer BRL may be disposed on a substrate SUB. The substrate SUB may be a glass substrate, but embodiments are not limited thereto. For example, the substrate SUB may be any one of various substrates used in a manufacturing process of a semiconductor device, such as a plastic substrate or a silicon substrate. The barrier layer BRL may provide a smooth interface for depositing an active pattern layer AP. For example, the barrier layer BRL may function to improve the crystal quality of the active pattern layer AP or reduce defects. The barrier layer BRL may include at least one of silica (SiO₂) and silicon nitride (SiNₓ), but embodiments are not limited thereto.

The active pattern layer AP may be disposed on the barrier layer BRL. In an embodiment, the active pattern layer AP may include an oxide semiconductor. For example, the active pattern layer AP may include indium gallium zinc oxide (IGZO) or indium tin gallium zinc oxide (ITGZO), but embodiments are not limited thereto. In an embodiment, the active pattern layer AP may include an amorphous oxide semiconductor. For example, the active pattern layer AP may include amorphous indium gallium zinc oxide (a-IGZO) or amorphous indium tin gallium zinc oxide (a-ITGZO), but embodiments are not limited thereto.

The active pattern layer AP may include a first region A1 and second regions A2 adjacent to the first region A1. The first region A1 may be an undoped region and may have lower conductivity than the second regions A2. The first region A1 may be a region through which carriers (e.g., holes or electrons) flow and may also be referred to as a channel region. The second regions A2 may be doped regions and may have higher conductivity than the first region A1. For example, the second regions A2 may be doped with an n-type dopant (e.g., NP in FIG. 8), but embodiments are not limited thereto. One of the second regions A2 may be a region that supplies carriers and may also be referred to as a source region. For example, one of the second regions A2 may refer to the second region A2 disposed on the left in FIG. 1. Another one of the second regions A2 may be a region where the carriers supplied from the source region are discharged after passing through the channel region, and may also be referred to as a drain region. For example, another one of the second regions A2 may refer to the second region A2 disposed on the right in FIG. 1.

A gate insulating pattern layer GIP may be disposed on the first region A1. The gate insulating pattern layer GIP may function to separate a gate electrode GE and the first region A1. The gate insulating pattern layer GIP may include an insulator. For example, the gate insulating pattern layer GIP may include silica (SiO₂), but embodiments are not limited thereto.

The gate electrode GE may be disposed on the gate insulating pattern layer GIP. The gate electrode GE may function to control the flow of carriers. The gate electrode GE may include metal. For example, the gate electrode GE may have a single-layer structure or a multi-layer structure including at least one of molybdenum (Mo), aluminum (Al), copper (Cu), and titanium (Ti).

A passivation layer PVL may be disposed on the barrier layer BRL, the active pattern layer AP, and the gate electrode GE. The passivation layer PVL may surround (or cover) the barrier layer BRL, the active pattern layer AP, the gate insulating pattern layer GIP, and the gate electrode GE. The passivation layer PVL may function to prevent external damage caused by scratches, moisture, or the like. The passivation layer PVL may include at least one of silica (SiO₂) and silicon nitride (SiNₓ), but embodiments are not limited thereto. The passivation layer PVL may include first and second contact holes CH1 and CH2 for an electrical connection structure.

A source electrode SE may be disposed on the passivation layer PVL. The source electrode SE may penetrate the passivation layer PVL and be electrically connected to one of the second regions A2. For example, the source electrode SE may be electrically connected to the source region through the first contact hole CH1. The source electrode SE may include metal. For example, the source electrode SE may have a single-layer structure or a multi-layer structure including at least one of aluminum (Al), copper (Cu), and titanium (Ti).

A drain electrode DE may be disposed on the passivation layer PVL. The drain electrode DE may penetrate the passivation layer PVL and be electrically connected to another one of the second regions A2. For example, the drain electrode DE may be electrically connected to the drain region through the second contact hole CH2. The drain electrode DE may include metal. For example, the drain electrode DE may have a single-layer structure or a multi-layer structure including at least one of aluminum (Al), copper (Cu), and titanium (Ti).

The characteristics of a thin film transistor TFT may be affected by a length L1 of the first region A1 (or channel region). Referring to FIG. 2, the active pattern layer AP including an oxide semiconductor may have the characteristic of absorbing gas flowing into from the outside. Accordingly, the length L1 of the first region A1 may be changed by gas flowing into upper and lower portions of the active pattern layer AP. For example, in case that the carrier concentration in the second regions A2 is changed by the gas and a length L2 of the second regions A2 increases, the length L1 of the first region A1 may decrease. In case that the length L1 of the first region A1 decreases, the characteristics of the thin film transistor TFT may change. For example, as the length L1 of the first region A1 decreases, a negative shift in which a threshold voltage of the thin film transistor TFT shifts in a negative direction may occur.

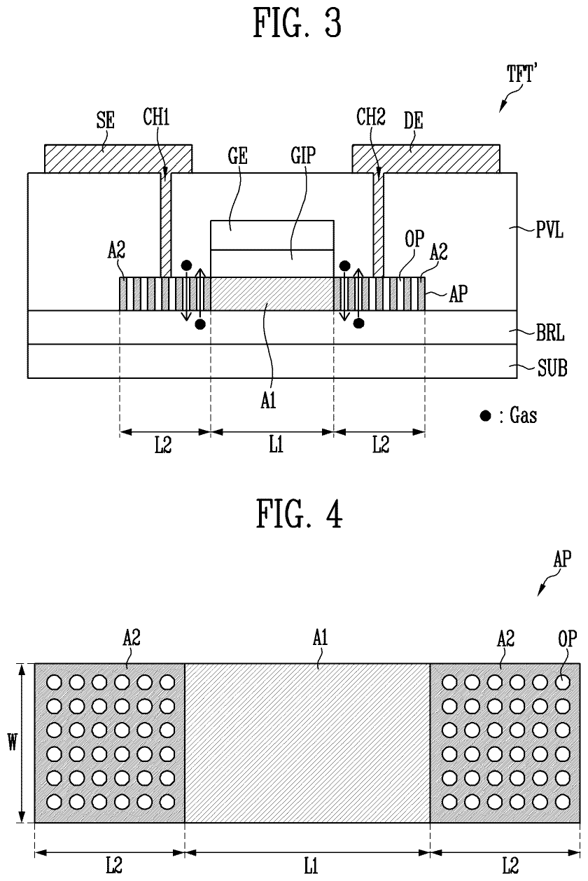

FIG. 3 is a schematic cross-sectional view illustrating a thin film transistor according to an embodiment. With regard to FIG. 3, content that overlaps with FIGS. 1 and 2 will be briefly described or omitted.

Referring to FIG. 3, the second regions A2 may include openings OP. For example, the source region and the drain region may include openings OP. The openings OP may refer to holes, lines, or the like penetrating the second regions A2. The openings OP may function to eliminate (or reduce) the influence of gas flowing into the second regions A2. For example, the openings OP may discharge gas flowing into upper portions of the second regions A2 to lower portions. For example, the openings OP may discharge gas flowing into the lower portions of the second regions A2 to the upper portions. For example, the openings OP may allow gas flowing into the second regions A2 to be discharged to the outside rather than remaining in the second regions A2. Accordingly, even in case that gas flows into the second regions A2, since the length L1 of the first region A1 and the length L2 of the second regions A2 remain unchanged, a change in characteristics of a thin film transistor TFT′, such as the negative shift, may not occur. For example, the influence of gas disposed on the thin film transistor TFT′ may be eliminated (or reduced) by the openings OP.

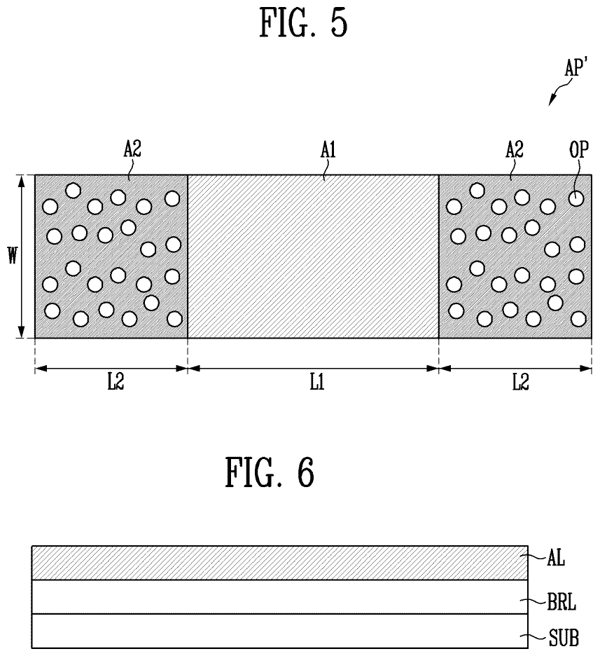

FIG. 4 is a schematic cross-sectional view illustrating an active pattern layer of FIG. 3 according to an embodiment. FIG. 5 is a schematic cross-sectional view illustrating the active pattern layer of FIG. 3 according to an embodiment.

Referring to FIG. 4, the openings OP of the active pattern layer AP may have a circular shape. However, embodiments are not limited thereto. For example, the openings OP may have one of various polygonal shapes such as a triangular shape or a square shape. Hereinafter, for convenience of description, it is assumed that the openings OP have a circular shape.

The size (or area) of each of the openings OP may vary according to the size (or area) of each of the second regions A2. For example, the size of the openings OP may vary according to the width W and the length L2 of the second regions A2. For example, the total size (or total area) occupied by the openings OP within the second regions A2 may be about 10% to about 80% of the total size (or total area) of the second regions A2. However, embodiments are not limited thereto. As an example, the size (or area) of each of the openings OP applied to a large panel, in which the width W of the second regions A2 is in a range of about 38 μm to about 60 μm and the length L2 of the second regions A2 is about 10 μm, may be in a range of about 1 μm to about 2 μm.

The openings OP may be regularly arranged within the second regions A2. For example, the openings OP may be arranged in a 6×6 matrix form within the second regions A2. However, embodiments are not limited thereto. For example, as long as the openings OP are arranged regularly, their shape or number is not limited thereto. Referring to FIG. 5, openings OP′ of an active pattern layer AP′ may be arranged irregularly in the second regions A2.

FIGS. 6 to 15 are a schematic cross-sectional view illustrating a method of manufacturing a thin film transistor according to an embodiment.

Referring to FIG. 6, after a barrier layer BRL is formed on a substrate SUB, an active layer AL may be formed on the barrier layer BRL. The active layer AL may include an oxide semiconductor such as indium gallium zinc oxide (IGZO) or indium tin gallium zinc oxide (ITGZO), but embodiments are not limited thereto. The active layer AL may be deposited by a thin film deposition method such as sputtering, pulse laser deposition, or electron beam deposition, but embodiments are not limited thereto.

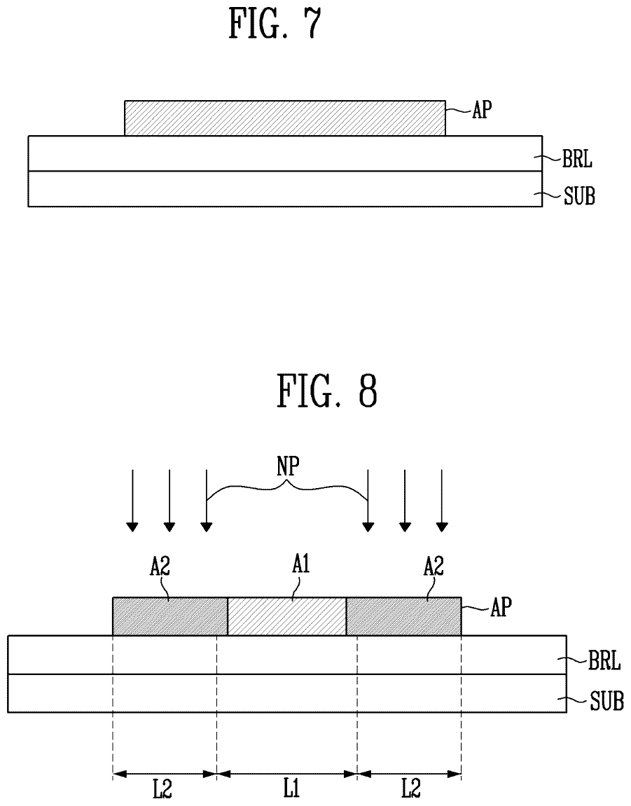

Referring to FIG. 7, an active pattern layer AP may be formed by patterning the active layer AL (see FIG. 6). The active pattern layer AP may be formed by a photolithography process, but embodiments are not limited thereto.

Referring to FIG. 8, the active pattern layer AP may be partially doped. For example, a first region A1 and second regions A2 adjacent to the first region A1 may be formed by an ion doping process. The first region A1 may be an undoped region, and the second regions A2 may be doped regions. The second regions A2 may be doped with an n-type dopant NP, but embodiments are not limited thereto.

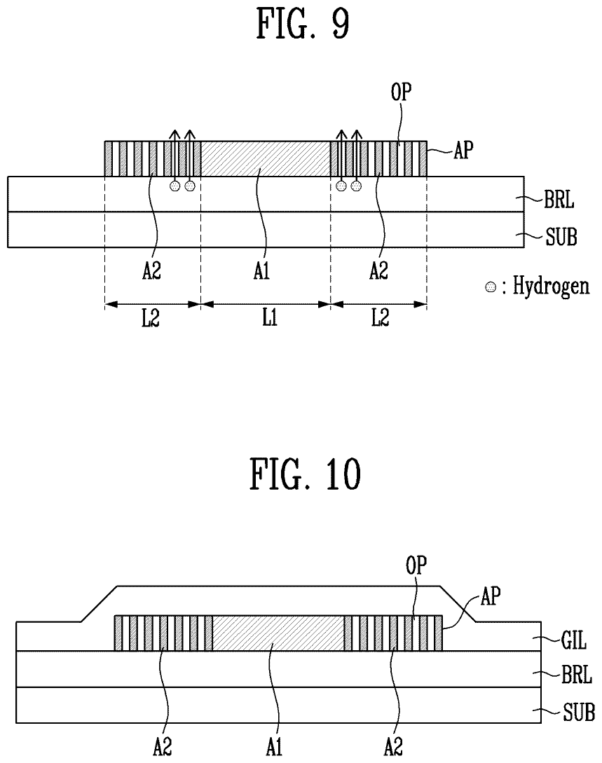

Referring to FIG. 9, openings OP may be formed in the second regions A2. For example, openings OP penetrating the second regions A2 may be formed by a method such as a punching process or an etching process. As the openings OP are formed in the second regions A2, gas flowing into the lower portion of the active pattern layer AP may be discharged to the outside. For example, hydrogen flowing into the second regions A2 from the barrier layer BRL may be discharged to the outside through the openings OP. For example, oxygen, moisture, or the like introduced from the outside may also be discharged to the outside through the openings OP. Accordingly, as the influence of gas originating from the barrier layer BRL is eliminated (or reduced), the length L1 of the first region A1 (or the channel region) and the length L2 of the second regions A2 (or the source region and the drain region) may remain unchanged without changing.

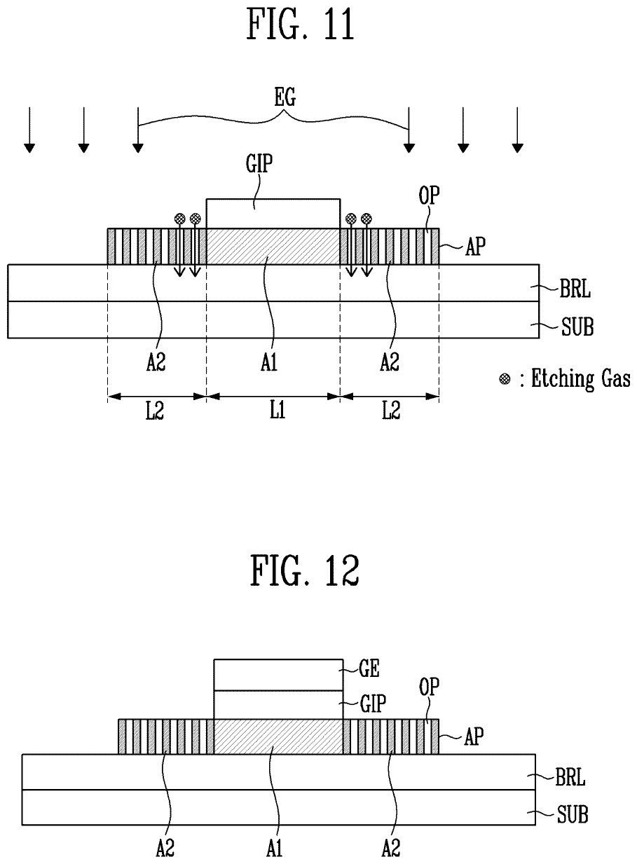

Referring to FIG. 10, a gate insulating layer GIL may be formed on the barrier layer BRL and the active pattern layer AP. Referring to FIG. 11, a gate insulating pattern layer GIP may be formed by patterning the gate insulating layer GIL (see FIG. 10). For example, the gate insulating pattern layer GIP may be formed through an etching process. As the openings OP are formed in the second regions A2, gas flowing into the upper portion of the active pattern layer AP may be discharged to the outside. For example, etching gas EG used in the etching process may be discharged to the outside through the openings OP. For example, oxygen, moisture, or the like introduced from the outside may also be discharged to the outside through the openings OP. Accordingly, as the influence of gas caused by the etching process is eliminated, the length L1 of the first region A1 and the length L2 of the second regions A2 may remain unchanged without changing.

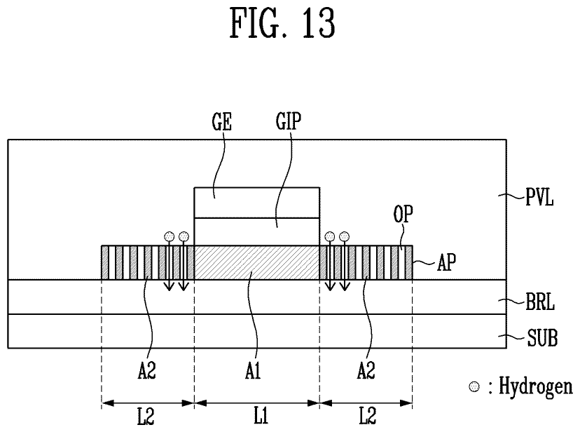

Referring to FIG. 12, a gate electrode GE may be formed on the gate insulating pattern layer GIP. Referring to FIG. 13, a passivation layer PVL may be formed to cover the barrier layer BRL, the active pattern layer AP, the gate insulating pattern layer GIP, and the gate electrode GE. As the openings OP are formed in the second regions A2, gas flowing into the upper portion of the active pattern layer AP may be discharged to the outside. For example, the passivation layer PVL including an inorganic material such as silica (SiO₂) or silicon nitride (SiNₓ) may block gases such as oxygen and moisture, but may have high hydrogen release characteristics. Hydrogen flowing into the second regions A2 from the passivation layer PVL may be discharged to the outside through the openings OP. For example, oxygen, moisture, or the like introduced (or permeated) from the outside may be discharged to the outside through the openings OP. Accordingly, as the influence of gas introducing (or permeating) from the passivation layer PVL is eliminated, the length L1 of the first region A1 and the length L2 of the second regions A2 may remain unchanged without changing.

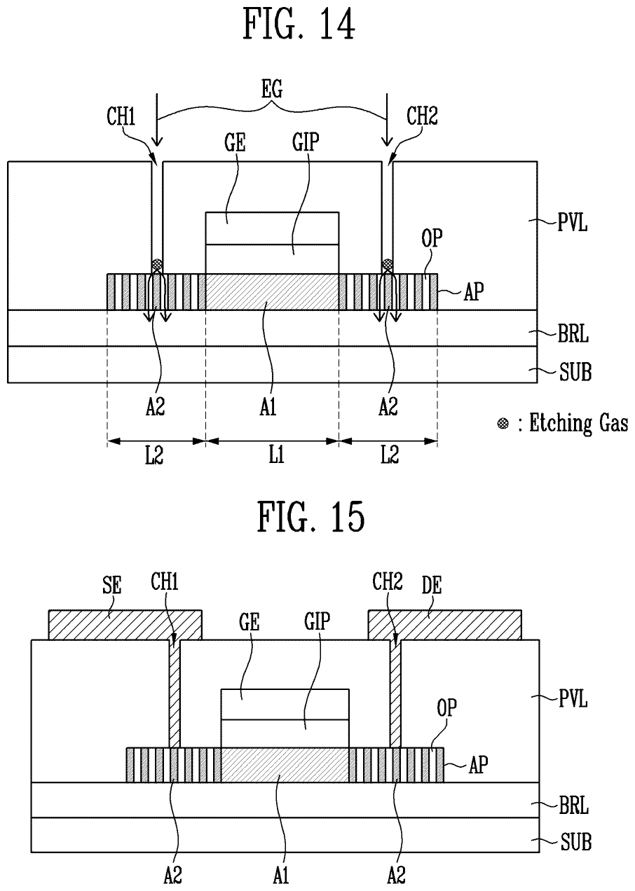

Referring to FIG. 14, first and second contact holes CH1 and CH2 penetrating the passivation layer PVL may be formed. The first and second contact holes CH1 and CH2 may be formed through an etching process. As the openings OP are formed in the second regions A2, gas flowing into the upper portion of the active pattern layer AP may be discharged to the outside. For example, etching gas EG used in the etching process may be discharged to the outside through the openings OP. For example, oxygen, moisture, or the like introduced from the outside may also be discharged to the outside through the openings OP. Accordingly, as the influence of gas caused by the etching process is eliminated, the length L1 of the first region A1 and the length L2 of the second regions A2 may remain unchanged without changing.

Referring to FIG. 15, a source electrode SE and a drain electrode DE may be formed. The source electrode SE may be electrically connected to one of the second regions A2 (or source region) through the first contact hole CH1. The drain electrode DE may be electrically connected to another one of the second regions A2 (or drain region) through the second contact hole CH2.

According to the embodiments, a thin film transistor capable of eliminating a change in characteristics due to gas flowing into upper and lower portions of the thin film transistor, and a method of manufacturing the thin film transistor may be provided.

However, effects of the disclosure are not limited to the above-described effect, and may be variously extended without departing from the spirit and scope of the disclosure.

A display device according to an embodiment is applicable to various types of electronic devices. In an embodiment, an electronic device includes the display device and may further include other modules or devices having additional functions in addition to the display device.

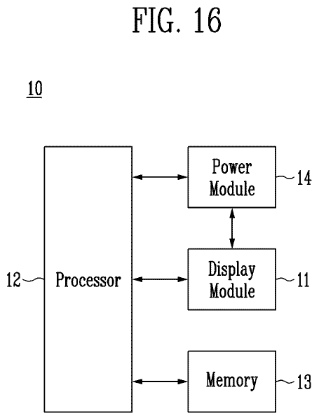

FIG. 16 is a block diagram of an electronic device according to an embodiment. Referring to FIG. 16, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

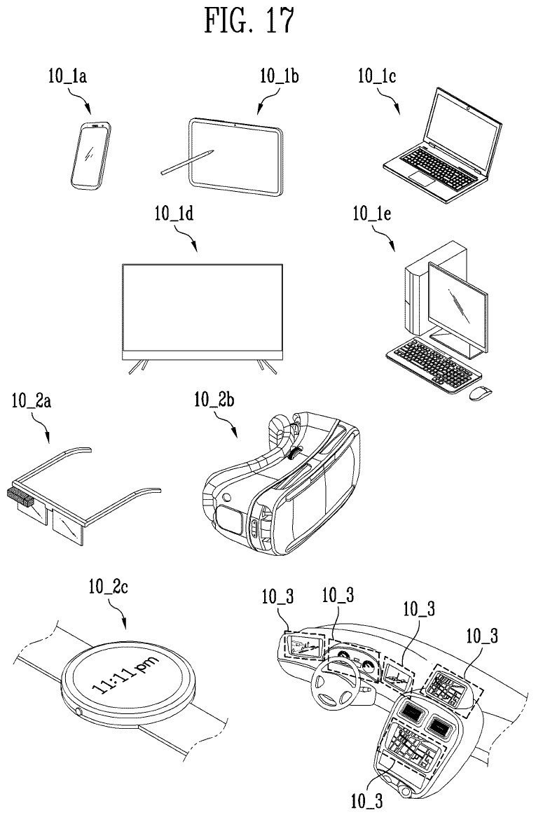

FIG. 17 shows schematic views of various embodiments of an electronic device.

Referring to FIG. 17, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although the disclosure has been described according to the above-described embodiments, it should be noted that the above-described embodiments are for describing the disclosure and not for limiting the scope of the disclosure. Those of ordinary skill in the art to which the disclosure pertains will understand that various modifications are possible within the scope of the technical spirit of the disclosure.

The scope of the disclosure is not limited to the details described in the detailed description of the specification, but should also be defined by the claims. It is to be construed that all changes or modifications derived from the meaning and scope of the claims and equivalent concepts thereof are included in the scope of the disclosure.

What is claimed is:

1. A thin film transistor comprising:
a substrate;
a barrier layer disposed on the substrate; and
an active pattern layer disposed on the barrier layer and including a first region and second regions adjacent to the first region,
wherein the second regions include openings.

2. The thin film transistor of claim 1, wherein the openings are arranged regularly.

3. The thin film transistor of claim 1, wherein the openings are arranged irregularly.

4. The thin film transistor of claim 1, wherein the openings have a circular shape or a polygonal shape.

5. The thin film transistor of claim 1, wherein a size of each of the openings varies according to a width of the active pattern layer and a length of each of the second regions.

6. The thin film transistor of claim 5, wherein a total size of the openings is about 10% to about 80% of a total size of the second regions.

7. The thin film transistor of claim 1, wherein the openings discharge gas flowing into the second regions, and
wherein the gas includes at least one of hydrogen, oxygen, moisture, and etching gas.

8. The thin film transistor of claim 1, wherein the active pattern layer includes an oxide semiconductor.

9. The thin film transistor of claim 1, further comprising:
a gate insulating pattern layer disposed on the first region;
a gate electrode disposed on the gate insulating pattern layer;
a passivation layer covering the barrier layer, the active pattern layer, the gate insulating pattern layer, and the gate electrode;
a source electrode penetrating the passivation layer and electrically connected to one of the second regions; and
a drain electrode penetrating the passivation layer and electrically connected to another one of the second regions.

10. A method of manufacturing a thin film transistor, the method comprising:
forming an active layer on a barrier layer on a substrate;
forming an active pattern layer by etching the active layer;
forming a first region and second regions adjacent to the first region by partially doping the active pattern layer; and
forming openings in the second regions.

11. The method of claim 10, wherein
the first region is an undoped region, and
the second regions are doped regions.

12. The method of claim 10, wherein the openings discharge hydrogen flowing into the second regions from the barrier layer.

13. The method of claim 10, further comprising:
forming a gate insulating layer covering the barrier layer and the active pattern layer; and
etching the gate insulating layer to form a gate insulating pattern layer on the first region.

14. The method of claim 13, wherein the openings discharge etching gas flowing into the second regions during a process of etching the gate insulating layer.

15. The method of claim 13, further comprising:
forming a gate electrode on the gate insulating pattern layer; and
forming a passivation layer to cover the barrier layer, the active pattern layer, the gate insulating pattern layer, and the gate electrode.

16. The method of claim 15, wherein the openings discharge hydrogen flowing into the second regions from the passivation layer.

17. The method of claim 15, further comprising:
forming a first contact hole and a second contact by etching the passivation layer.

18. The method of claim 17, wherein the openings discharge etching gas flowing into the second regions during a process of etching the passivation layer.

19. The method of claim 17, further comprising:
forming a source electrode electrically connected to one of the second regions through the first contact hole; and
forming a drain electrode electrically connected to another one of the second regions through the second contact hole.

20. An electronic device comprising:
a processor to provide input image data; and
a display device to display an image based on the input image data, the display device including a thin film transistor,
wherein the thin film transistor comprises:
a substrate;
a barrier layer disposed on the substrate; and
an active pattern layer disposed on the barrier layer and including a first region and second regions adjacent to the first region, and
wherein the second regions include openings.
